(19) United States
(12) Patent Application Publication
(10) Pub. No.: US 2007/0034958 A1
(43) Pub. Date: Feb. 15, 2007

(54) Electro-static discharge protecting device and method for fabricating the same

(75) Inventor: San Hong Kim, Gyeonggi-do (KR)

Correspondence Address: FINNEGAN, HENDERSON, FARABOW, GARRETT & DUNNER;LLP, 901 NEW YORK AVENUE, NW, WASHINGTON, DC, 20001-4413, US

(73) Assignee: Dongbu Electronics Co., Ltd.

(21) Appl. No.: 11/501,871

(22) Filed: Aug. 10, 2006

(30) Foreign Application Priority Data
Aug. 11, 2005 (KR) 10-2005-73765

(51) Int. Cl. H01L 23/62

(52) U.S. Cl. 257/355

(57) ABSTRACT

Provided are an ESD protecting device and a method for fabricating the same. The ESD protecting device includes a semiconductor substrate having a first conductivity type, the semiconductor substrate having a field region and an active region; first and second device isolation layers formed in the field region; a first impurity region and a second impurity region in the active region and isolated by the first device isolation layer, the first impurity region and the second impurity region both having a second conductivity type; a third impurity region isolated from the second impurity region by the second device isolation layer, the third impurity region having the first conductivity type; and a fourth impurity region formed in a portion of the semiconductor substrate below the first impurity region, the fourth impurity region having the first conductivity type and having a lower impurity concentration than the third impurity region.

### RELATED APPLICATION

This application is based upon and claims the benefit of priority to Korean Application No. 10-2005-73765, filed on Aug. 11, 2005, the entire contents of which are incorporated herein by reference.

### BACKGROUND

1.Technical Field

The present invention relates to an electro-static discharge (ESD) protecting device and a method for fabricating the same.

2. Description of the Related Art

In general, ESD occurs when a user who is electro-statically charged by friction and induction touches electronic components. Also, integrated circuits (ICs), particularly, ICs including metal oxide semiconductor (MOS) transistors, are vulnerable to ESD damage. The ESD charge may transfer to an input/output pad, a power pin or another IC pad, causing fatal damage to a semiconductor junction, a dielectric, an interconnection part, or other elements of the IC.

A semiconductor device with a small feature size and a high degree of integration generally includes an ESD protecting device used to protect ESD-sensitive components therein. The ESD protecting device may be a gate-grounded NMOS (GGNMOS). The GGNMOS includes a lateral parasitic bipolar transistor that serves to bypass static electricity.

The ESD protecting device having the GGNMOS structure is effective for digital input/output (I/O) devices that are not sensitive to a leakage current. However, as the size of the device gets smaller, the GGNMOS structure has a higher leakage current because of a decrease in thickness of a gate insulating layer, an increase in P-type impurity concentration of a P-type semiconductor substrate, an increase in lightly-doped drain (LDD) concentration, etc. As a result, applications of an ESD protecting device having a GGNMOS structure in circuits with analog I/O devices, which are relatively sensitive to a subtle current change, are limited.

In addition, ESD protecting devices having a GGNMOS structure are difficult to scale down, because a gate electrode of the GGNMOS is an essential part in providing ESD protection and cannot be easily scaled.

As an alternative, an ESD protecting device using a field transistor having no gate electrode has drawn attention. Because a field transistor does not have a gate electrode, the leakage current may be reduced. Also, the field transistor does not exhibit a gate-induced barrier lowering (GIBL) effect, and thus has a relatively high ESD trigger voltage.

However, the related art field transistor has a high breakdown voltage, as a result of which it is difficult to protect internal components from the ESD.

### SUMMARY

Accordingly, the present invention is directed to an ESD protecting device and a method for fabricating the same that substantially obviate one or more problems due to limitations and disadvantages of the related art.

Embodiments consistent with the present invention provide an ESD protecting device that includes a field transistor formed by applying an additional impurity ion implanting process to result in a low breakdown voltage. Embodiments consistent with the present invention also provide an ESD protecting device that includes a field transistor structure without a gate electrode, unlike a GGNMOS structure, so that a leakage current is reduced, and thus internal components are protected. Embodiments consistent with the present invention further provide a fabrication method of the ESD protecting device.

Additional advantages and features of the invention will be set forth in part in the description which follows and in part will become apparent to those having ordinary skill in the art upon examination of the following or may be learned from practice of the invention. The objectives and other advantages of the invention may be realized and attained by the structure particularly pointed out in the written description and claims hereof as well as the appended drawings.

Consistent with embodiments of the present invention, an ESD (electro-static discharge) protecting device includes a semiconductor substrate having a first conductivity type, the semiconductor substrate having a field region and an active region; first and second device isolation layers formed in the field region; a first impurity region and a second impurity region in the active region and isolated by the first device isolation layer, the first impurity region and the second impurity region both having a second conductivity type; a third impurity region isolated from the second impurity region by the second device isolation layer, the third impurity region having the first conductivity type; and a fourth impurity region formed in a portion of the semiconductor substrate below the first impurity region, the fourth impurity region having the first conductivity type and having a lower impurity concentration than the third impurity region.

Consistent with embodiments of the present invention, a method for fabricating an ESD (electro-static discharge) protecting device includes forming a first device isolation layer and a second device isolation layer in a field region of a semiconductor substrate, the semiconductor substrate having a first conductivity type; forming a first impurity region and a second impurity region in an active region of the semiconductor substrate, the first and second impurity regions both having a second conductivity type and being isolated by the first device isolation layer; forming a third impurity region in the semiconductor substrate and isolated from the second impurity region by the second device isolation layer, the fourth impurity region having the first conductivity type; and forming a fourth impurity region in a portion of the semiconductor substrate below the first impurity region, the fourth impurity region having the first conductivity type and having a lower impurity concentration than the third impurity region.

It is to be understood that both the foregoing general description and the following detailed description of the present invention are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this application, illustrate embodiment(s) of the invention and together with the description serve to explain the principle of the invention. In the drawings:

FIG. 1 is a cross-sectional view of an ESD protecting device consistent with an embodiment of the present invention; and

FIGS. 2 to 7 are cross-sectional views illustrating fabrication processes of the ESD protecting device consistent with an embodiment of the present invention.

### DETAILED DESCRIPTION

Reference will now be made in detail to embodiments of the present invention, examples of which are illustrated in the accompanying drawings.

An ESD protecting device and a method of fabricating the same consistent with embodiments of the present invention will now be described in detail with reference to the accompanying drawings.

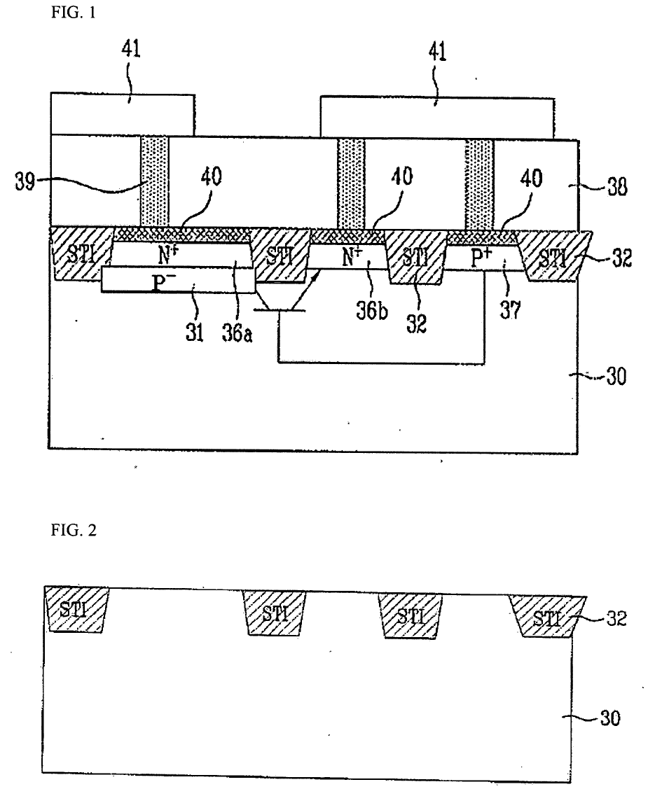

FIG. 1 is a cross-sectional view of an ESD protecting device consistent with the embodiments of the present invention.

Referring to FIG. 1, the ESD protecting device consistent with the embodiments of the present invention includes a P-type semiconductor substrate 30 in which active regions and field regions are defined, and a plurality of device isolation layers 32 in the field regions. For example, device isolation layers 32 may be formed by forming shallow trenches in the field region of the P-type semiconductor substrate 30 and filling the trenches with an insulating material to form shallow trench isolation layers.

A first high-concentration N-type impurity region 36a and a second high-concentration N-type impurity region 36b, respectively constituting a drain region and a source region, are formed in a surface portion of the P-type semiconductor substrate 30 in the active region by high-concentration N-type impurity ion implantation. A high-concentration P-type impurity region 37 may be formed also in a surface portion of the P-type semiconductor substrate 30 also in the active region. The first and second high-concentration N-type impurity regions 36a and 36b, and the high-concentration P-type impurity region 37 are isolated from each other by the device isolation layers 32.

In one aspect, the first high-concentration N-type impurity region 36a serves as a drain region, and the second high-concentration N-type impurity region 36b serves as a source region. In another aspect, the P-type semiconductor substrate 30 has a concentration of 1×10¹⁶-1×10¹⁷ atoms/cm³. In a further aspect, each of the first and second high-concentration N-type impurity regions 36a and 36b has a concentration of 1×10²⁰-10×10²² atoms/cm³.

Referring again to FIG. 1, a low-concentration P-type impurity region 31 serving to lower the breakdown voltage may be formed in a portion of the P-type semiconductor substrate 30 under the first high-concentration N-type impurity region 36a. The low-concentration P-type impurity region 31 may have a concentration of 1×10¹⁷-1×10¹⁹ atoms/cm³, which is higher than that of the P-type semiconductor substrate 30 and lower than that of the first and second high-concentration N-type impurity regions 36a and 36b. Thus, the low-concentration P-type impurity region 31 may control breakdown current and may prevent leakage current. If, on the other hand, the low-concentration P-type impurity region 31 has a lower concentration than the P-type semiconductor substrate 30, it cannot serve as a doped region; if the low-concentration P-type impurity region 31 has a higher concentration than the first and second high-concentration N-type impurity regions 36a and 36b, an excessive leakage current results.

FIG. 1 further shows a silicide layers 40 formed on surfaces of the high-concentration N-type impurity regions 36a and 36b and the high-concentration P-type impurity region 37. An interlayer insulating layer 38 is formed on an entire surface of the substrate including the high-concentration N-type impurity regions 36a and 36b, the high-concentration P-type impurity region 37, and the silicide layers 40. Contact holes are formed in the interlayer insulating layer 38 so as to expose a portion of the silicide layers 40 on the high-concentration N-type impurity regions 36a and 36b and the high-concentration P-type impurity region 37. A plurality of contact plugs 39 are respectively formed in the contact holes to be electrically connected to the silicide layers 40 on the high-concentration N-type impurity regions 36a and 36b and the high-concentration P-type impurity region 37. A plurality of metal lines 41 may be formed to be connected to the contact plugs 39.

Even though it is exemplarily described in FIG. 1 that the ESD protecting device uses a P-type semiconductor substrate, the present invention is not limited thereto.

Also, even though it is exemplarily described in FIG. 1 that the ESD protecting device uses a field transistor, the present invention is not limited thereto.

A method for fabricating the ESD protecting device shown in FIG. 1 will be described below, with reference to FIGS. 2 to 7.

Referring to FIG. 2, an active region and a field region are defined on a p-type or n-type semiconductor substrate 30, and the field region is etched to a predetermined depth to form a plurality of shallow trenches. The trenches are filled with an insulation layer such as an oxide layer, and are polished through a chemical mechanical polishing (CMP) process such that the insulation layer remains inside the trenches to form a plurality of device isolation layers 32.

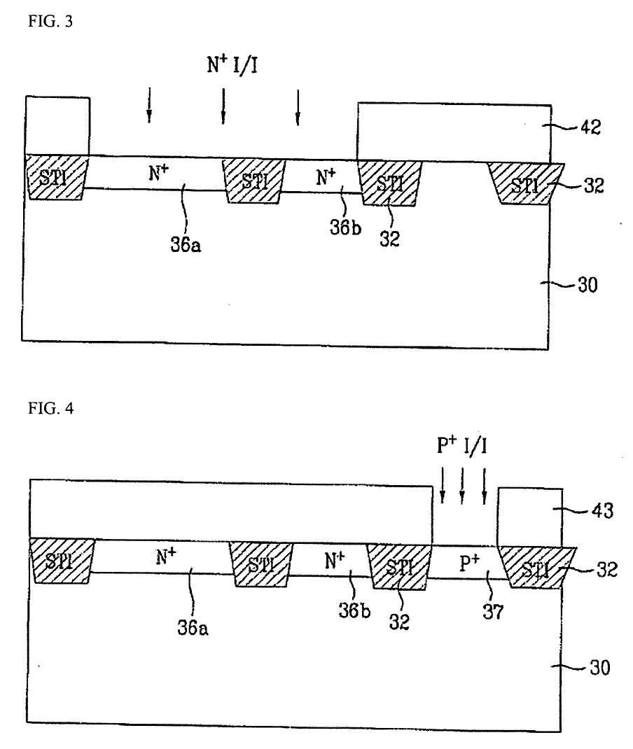

Referring to FIG. 3, first and second high-concentration N-type impurity regions 36a and 36b are formed by forming a first photosensitive layer 42 on an entire surface of the semiconductor substrate 30, patterning the first photosensitive layer 42 through exposure and developing processes, where the patterned first photosensitive layer 42 exposes portions of the active region in which the first and second high-concentration N-type impurity regions 36a and 36b are to be formed, and implanting high-concentration N-type impurity ions into the active region using the patterned first photosensitive layer 42 as a mask. In one aspect, the process of implanting high-concentration N-type impurity ions may be performed using N-type impurity ions such as P and As at a concentration of 1×10¹⁵ atoms/cm² or more, and an ion implanting energy of 50 KeV or less. Therefore, each of the first and second high-concentration N-type impurity regions 36a and 36b has concentration of 1×10²⁰-1×10²² atoms/cm³.

Referring to FIG. 4, the first photosensitive layer 42 is removed, and a second photosensitive layer 43 is formed on an entire surface of the semiconductor substrate 30 and patterned through exposure and developing processes to expose portions of the active region in which high-concentration P-type impurity region 37 is to be formed. Next, a high-concentration P-type impurity region 37 is formed by implanting high-concentration P-type impurity ions into the active region using the patterned second photosensitive layer 43 as a mask. In one aspect, the process of implanting high-concentration P-type impurity ions may be performed by implanting P-type impurity ions such as B at a concentration of 10¹⁵ atoms/cm² or more and with an ion implanting energy of 20 KeV or less.

Referring to FIG. 5, the second photosensitive layer 43 is removed, and a third photosensitive layer 44 is formed on an entire surface of the semiconductor substrate 30 and patterned through exposure and developing processes to expose portions of the active region in which the high-concentration N-type impurity region 36a is formed. Next, a low-concentration P-type impurity region 31 is formed by implanting P-type impurity ions into a portion of the substrate 30 below the first high-concentration N-type impurity region 36a using the patterned third photosensitive layer 44 as a mask. In one aspect, the process of implanting low-concentration P-type impurity ions can be performed by implanting P-type impurity ions such as B at a concentration of 3×10¹³-7×10¹³ atoms/cm² and with an ion implanting energy of 60-100 KeV. Therefore, the low-concentration P-type impurity region 31 has concentration of 1×10¹⁷-1×10¹⁹ atoms/cm³, which is higher than that of the P-type semiconductor substrate 30, and lower than that of the first and second high-concentration N-type impurity regions 36a and 36b.

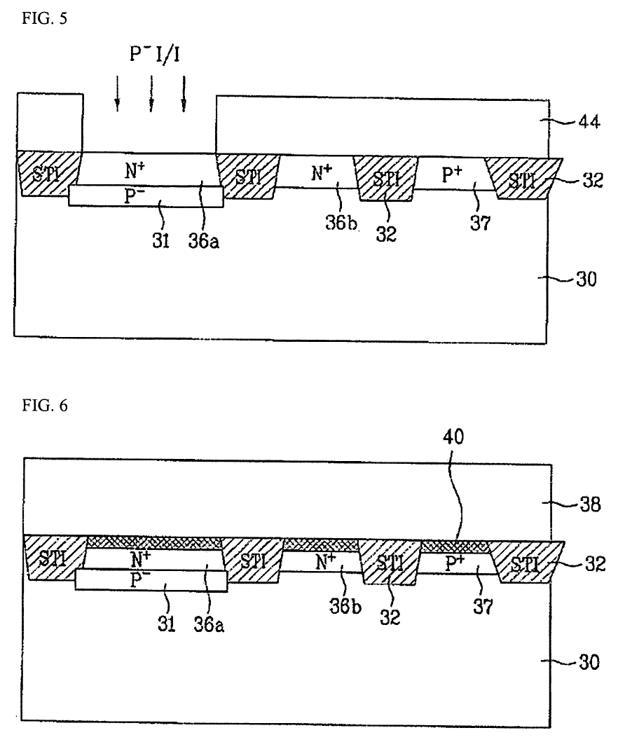

Referring to FIG. 6, the third photoresist layer 44 is removed, and a silicide process is performed to form silicide layer 40 on a surface of the first and second high-concentration N-type impurity regions 36a and 36b, and the high-concentration P-type impurity region 37. Interlayer insulating layer 38 is then formed on an entire surface of the substrate including the silicide layer 40. During the silicide process, a metal (not shown) having a high melting point is deposited and annealed on an entire surface of the semiconductor substrate 30. As a result of the annealing, a silicide layer 40 is formed on a surface where the metal contacts the semiconductor substrate 30. Non-reacted portions of the metal are removed.

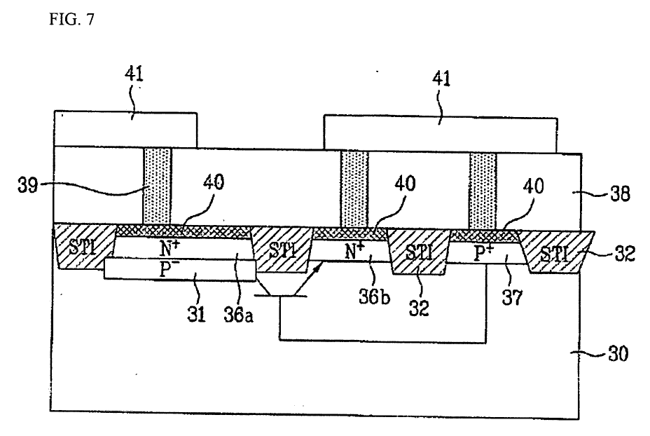

Referring to FIG. 7, contact holes are formed in the interlayer insulating layer 38 to expose the silicide layer 40 formed on a surface of the first and second high-concentration N-type impurity regions 36a and 36b, and the high-concentration P-type impurity region 37. Contact plugs 39 are formed inside the contact holes. Metal line 41 is formed to be connected to the contact plug 39.

As shown in FIG. 1 and FIGS. 2-7, the ESD protecting device consistent with embodiments of the present invention has a field transistor including a parasitic transistor formed of high-concentration N-type impurity regions 36a and 36b and high-concentration P-type impurity region 37. Because of the low-concentration P-type impurity region 31, the field transistor has a low breakdown voltage. Therefore, the ESD protecting device consistent with embodiments of the present invention has a low breakdown voltage and a low leakage current. As a result, the ESD protecting device consistent with embodiments of the present invention can be used for protecting analog input/output devices that are sensitive to a current variation.

It will be apparent to those skilled in the art that various modifications and variations can be made in the present invention. Thus, it is intended that the present invention covers the modifications and variations of this invention provided they come within the scope of the appended claims and their equivalents.

What is claimed is:

1. An ESD (electro-static discharge) protecting device, comprising:
a semiconductor substrate having a first conductivity type, the semiconductor substrate having a field region and an active region;
first and second device isolation layers formed in the field region;
a first impurity region and a second impurity region in the active region and isolated by the first device isolation layer, the first impurity region and the second impurity region both having a second conductivity type;
a third impurity region isolated from the second impurity region by the second device isolation layer, the third impurity region having the first conductivity type; and
a fourth impurity region formed in a portion of the semiconductor substrate below the first impurity region, the fourth impurity region having the first conductivity type and having a lower impurity concentration than the third impurity region.

2. The ESD protecting device of claim 1, further comprising:
a silicide layer formed on a surface of the first impurity region, the second impurity region, and the third impurity region;
an interlayer insulating layer formed on an entire surface of the substrate, the interlayer insulating layer having a contact hole exposing the silicide layer;
a contact plug formed in the contact hole; and
a metal line formed to be connected to the contact plug.

3. The ESD protecting device of claim 1, wherein the fourth impurity region has a higher concentration than the semiconductor substrate.

4. The ESD protecting device of claim 1, wherein the fourth impurity region has a lower concentration than the first impurity region and the second impurity region.

5. The ESD protecting device of claim 1, wherein the fourth impurity region has a concentration of about 1×10¹⁷-1×10¹⁹ atoms/cm³.

6. The ESD protecting device of claim 1, wherein the first impurity region and the second impurity region each have a concentration of about 1×10²⁰-1×10²² atoms/cm³.

7. The ESD protecting device of claim 1, wherein the semiconductor substrate has a concentration of about 1×10¹⁶-1×10¹⁷ atoms/cm³.

8. The ESD protecting device of claim 1, wherein the ESD protecting device comprises a field transistor.

9. The ESD protecting device of claim 1, wherein the first impurity region comprises a drain region, and the second impurity region comprises a source region.

10. A method for fabricating an ESD (electro-static discharge) protecting device, the method comprising:
forming a first device isolation layer and a second device isolation layer in a field region of a semiconductor substrate, the semiconductor substrate having a first conductivity type;
forming a first impurity region and a second impurity region in an active region of the semiconductor substrate, the first and second impurity regions both having a second conductivity type and being isolated by the first device isolation layer;
forming a third impurity region in the semiconductor substrate and isolated from the second impurity region by the second device isolation layer, the fourth impurity region having the first conductivity type; and
forming a fourth impurity region in a portion of the semiconductor substrate below the first impurity region, the fourth impurity region having the first conductivity type and having a lower impurity concentration than the third impurity region.

11. The method of claim 10, further comprising:
forming a silicide layer on a surface of the first impurity region, the second impurity region, and the third impurity region;
forming an interlayer insulating layer having a contact hole exposing the silicide layer on an entire surface of the semiconductor substrate;
forming a contact plug in the contact hole; and
forming a metal line to be connected to the contact plug.

12. The method of claim 10, wherein forming the first and second impurity regions comprises implanting N-type impurity ions having a concentration of about 1×10¹⁵ atoms/cm² or more at an ion implanting energy of about 50 KeV or less.

13. The method of claim 10, wherein the first and second impurity regions are formed to have a concentration of about 1×10²⁰-1×10²² atoms/cm³.

14. The method of claim 10, wherein forming the third impurity region comprises implanting P-type impurity ions having a concentration of about 1×10¹⁵ atoms/cm² or more at an ion implanting energy of about 20 KeV or less.

15. The method of claim 10, wherein forming the fourth impurity region comprises implanting P-type impurity ions having a concentration of about 3×10¹³-7×10¹³ atoms/cm².

16. The method of claim 10, wherein the fourth impurity region has a concentration of about 1×10¹⁷-1×10¹⁹ atoms/cm³.

17. The method of claim 15, wherein the P-type impurity ions comprise boron ions.

18. The method of claim 10, wherein forming the fourth impurity region comprises implanting P-type impurity ions at an energy of about 60-100 KeV.

19. The method of claim 10, wherein the semiconductor substrate has a concentration of about 1×10¹⁶-1×10¹⁷ atoms/cm³.

20. The method of claim 10, wherein the fourth impurity region has a higher concentration than the semiconductor substrate, and has a lower concentration than the first and second impurity regions.
